(19) United States
(12) Patent Application Publication
(10) Pub. No.: US 2026/0333336 A1
(43) Pub. Date: Oct. 22, 2026

(54) NETWORK ASSISTANCE AND TRIGGER BASED REPORTING FOR ENERGY EFFICIENT QUANTIZATION

(71) Applicant: QUALCOMM Incorporated, San Diego, CA (US)

(72) Inventors: Narayan PRASAD, Westfield, NJ (US); Igor GUTMAN, Hod HaSharon (IL); Wooseok NAM, San Diego, CA (US); Junyi LI, Greentown, PA (US); Tao LUO, San Diego, CA (US); Sony AKKARAKARAN, Poway, CA (US)

(21) Appl. No.: 19/182,008

(22) Filed: Apr. 17, 2025

(51) Int. Cl. H04W 72/044; H04W 24/10; H04W 72/0446; H04W 72/51

(52) U.S. Cl. CPC H04W 72/046; H04W 24/10; H04W 72/0446; H04W 72/51

(57) ABSTRACT

This disclosure provides methods, components, devices and systems for network assistance and trigger based reporting for energy efficient quantization. For example, a user equipment (UE) may receive a message that identifies assistance information associated with a probability distribution function (PDF), the PDF corresponding to a probability distribution of characteristics of input signals to be received by the UE over a wireless channel. The UE may quantize an input signal received over the wireless channel, wherein quantizing the input signal comprises selecting one or more threshold values, one or more sequence orders, or both, during an analog-to-digital conversion (ADC) process that is based at least in part on the assistance information.

### TECHNICAL FIELD

This disclosure relates generally to wireless communication, and more specifically to systems, devices, methods, and techniques associated with network assistance and trigger based reporting for energy efficient quantization.

### DESCRIPTION OF THE RELATED TECHNOLOGY

Communication systems are deployed to provide communication services such as voice, video, packet data, messaging, or broadcast, among others. A communication system may include a wireless communication network (such as a radio access network (RAN)) that supports communication between wireless communication devices such as network entities (such as base stations), client devices (such as one or more user equipments (UEs)), and others. Such devices may communicate with one another using a variety of protocols (such as radio access technologies (RATs)), including those of cellular-based systems such as fourth generation (4G) systems (such as Long Term Evolution (LTE) systems), fifth generation (5G) systems (such as 5G New Radio (5G-NR) systems), and sixth generation (6G) systems. A wireless communication network may support communication by implementing system resources (such as frequency resources, time resources, spatial resources) in accordance with a wireless communication protocol.

### SUMMARY

The systems, methods, and devices of this disclosure each have several innovative aspects, no single one of which is solely responsible for the desirable attributes disclosed herein. The following is a summary of some non-limiting aspects of the disclosure:

A method for wireless communications by a UE is described. The method may include receiving a message that identifies assistance information associated with a probability distribution function (PDF), the PDF corresponding to a probability distribution of characteristics of input signals to be received by the UE over a wireless channel and quantizing an input signal received over the wireless channel, where quantizing the input signal includes selecting one or more threshold values, one or more sequence orders, or both, during an analog-to-digital conversion (ADC) process that is based on the assistance information.

A UE for wireless communications is described. The UE may include a processing system that includes processor circuitry and memory circuitry that stores code. The processing system may be configured to cause the UE to receive a message that identifies assistance information associated with a PDF, the PDF corresponding to a probability distribution of characteristics of input signals to be received by the UE over a wireless channel and quantize an input signal received over the wireless channel, where quantizing the input signal includes selecting one or more threshold values, one or more sequence orders, or both, during an ADC process that is based on the assistance information.

Another UE for wireless communications is described. The UE may include means for receiving a message that identifies assistance information associated with a PDF, the PDF corresponding to a probability distribution of characteristics of input signals to be received by the UE over a wireless channel and means for quantizing an input signal received over the wireless channel, where quantizing the input signal includes selecting one or more threshold values, one or more sequence orders, or both, during an ADC process that is based on the assistance information.

A non-transitory computer-readable medium storing code for wireless communications is described. The code may include instructions executable by one or more processors to receive a message that identifies assistance information associated with a PDF, the PDF corresponding to a probability distribution of characteristics of input signals to be received by the UE over a wireless channel and quantize an input signal received over the wireless channel, where quantizing the input signal includes selecting one or more threshold values, one or more sequence orders, or both, during an ADC process that is based on the assistance information.

In some examples of the method, user equipment (UEs), and non-transitory computer-readable medium described herein, the assistance information includes statistical information corresponding to the probability distribution across a spatial domain, across a time domain, or both.

Some examples of the method, user equipment (UEs), and non-transitory computer-readable medium described herein may further include operations, features, means, or instructions for generating the PDF based on the assistance information.

In some examples of the method, user equipment (UEs), and non-transitory computer-readable medium described herein, the assistance information may be on a location basis, a frequency band basis, a time period basis, or any combination thereof.

A method for wireless communications by a network entity is described. The method may include receiving a UE capability report that indicates support by a UE for using assistance information during quantizing an input signal, transmitting, to the UE and based on the UE capability report, a message that identifies assistance information associated with a PDF, the PDF corresponding to a probability distribution of characteristics of input signals to be received by the UE over a wireless channel, and transmitting an input signal to the UE over the wireless channel, where the UE quantizes the input signal by selecting one or more threshold values, one or more sequence orders, or both, during an ADC process that is based on the assistance information.

A network entity for wireless communications is described. The network entity may include a processing system that includes processor circuitry and memory circuitry that stores code. The processing system may be configured to cause the network entity to receive a UE capability report that indicates support by a UE for using assistance information during quantizing an input signal, transmit, to the UE and based on the UE capability report, a message that identifies assistance information associated with a PDF, the PDF corresponding to a probability distribution of characteristics of input signals to be received by the UE over a wireless channel, and transmit an input signal to the UE over the wireless channel, where the UE quantizes the input signal by selecting one or more threshold values, one or more sequence orders, or both, during an ADC process that is based on the assistance information.

Another network entity for wireless communications is described. The network entity may include means for receiving a UE capability report that indicates support by a UE for using assistance information during quantizing an input signal, means for transmitting, to the UE and based on the UE capability report, a message that identifies assistance information associated with a PDF, the PDF corresponding to a probability distribution of characteristics of input signals to be received by the UE over a wireless channel, and means for transmitting an input signal to the UE over the wireless channel, where the UE quantizes the input signal by selecting one or more threshold values, one or more sequence orders, or both, during an ADC process that is based on the assistance information.

A non-transitory computer-readable medium storing code for wireless communications is described. The code may include instructions executable by one or more processors to receive a UE capability report that indicates support by a UE for using assistance information during quantizing an input signal, transmit, to the UE and based on the UE capability report, a message that identifies assistance information associated with a PDF, the PDF corresponding to a probability distribution of characteristics of input signals to be received by the UE over a wireless channel, and transmit an input signal to the UE over the wireless channel, where the UE quantizes the input signal by selecting one or more threshold values, one or more sequence orders, or both, during an ADC process that is based on the assistance information.

In some examples of the method, network entities, and non-transitory computer-readable medium described herein, the assistance information includes statistical information corresponding to the probability distribution across a spatial domain, across a time domain, or both.

In some examples of the method, network entities, and non-transitory computer-readable medium described herein, the assistance information may be on a location basis, a frequency band basis, a time period basis, or any combination thereof.

### BRIEF DESCRIPTION OF THE DRAWINGS

FIG. 1 shows an example of a wireless communication system.

FIG. 2 shows an example of a signaling diagram that supports network assistance and trigger based reporting for energy efficient quantization.

FIG. 3 shows an example of an analog-to-digital conversion (ADC) configuration that supports network assistance and trigger based reporting for energy efficient quantization.

FIG. 4 shows an example of a distribution estimator module (DEM) that supports network assistance and trigger based reporting for energy efficient quantization.

FIG. 5 shows a block diagram of a processing system that supports network assistance and trigger based reporting for energy efficient quantization.

FIG. 6 shows a diagram of a system including a device that supports network assistance and trigger based reporting for energy efficient quantization.

FIG. 7 shows a block diagram of a processing system that supports network assistance and trigger based reporting for energy efficient quantization.

FIG. 8 shows a diagram of a system including a device that supports network assistance and trigger based reporting for energy efficient quantization.

FIGS. 9 through 12 show flowcharts illustrating methods that support network assistance and trigger based reporting for energy efficient quantization.

Details of aspects and advantages of the subject matter in this disclosure are set forth in the drawings and accompanying descriptions. Like reference numbers and designations in the various drawings indicate like elements.

### DETAILED DESCRIPTION

A communication system may include a radio access network (RAN) that supports wireless communication. Communication of a RAN may be performed in accordance with one or more radio access technologies (RATs), including 4G, 5G, or 6G, among others, including technologies not explicitly mentioned herein. A RAT may employ access technologies (such as multiplexing technologies) including code division multiple access (CDMA), time division multiple access (TDMA), frequency division multiple access (FDMA), orthogonal FDMA (OFDMA), single-carrier FDMA (SC-FDMA), time division synchronous code division multiple access (TD-SCDMA), or discrete Fourier transform spread orthogonal frequency division multiplexing (DFT-S-OFDM), among others. A RAT may support one or more service types, including machine type communication (MTC), massive MTC (mMTC), Internet of Things (IoT), narrowband IoT (NB-IoT), reduced capability (RedCap), enhanced mobile broadband (eMBB), ultra-reliable low-latency communication (URLLC), or public safety, among others.

To support these and other target verticals, a communication system (such as a RAN) may be designed to implement one or more of a modularized functional infrastructure, a disaggregated and service-based network architecture, network function virtualization, network slicing, multi-access edge computing, spatial processing or multipath techniques, IoT or RedCap device connectivity and management, industrial connectivity, licensed and unlicensed spectrum access, sidelink or other device-to-device (D2D) direct communication (such as vehicle-to-everything (V2X)), frequency spectrum expansion, overlapping spectrum use, small cell deployments, non-terrestrial network (NTN) deployments, device aggregation, advanced duplex communication (such as sub-band full-duplex (SBFD)), multiple-subscriber implementations, high-precision positioning, radio frequency (RF) sensing, network energy savings (NES), low-power signaling and radios, or artificial intelligence or machine learning (AI/ML), among other examples.

The foregoing and other technological improvements may support use cases such as voice calls, messaging, data transfer, streaming, wireless data centers, extended reality (XR) and metaverse applications, vehicle connectivity, holographic and mixed reality communication, autonomous and collaborative robots, sensing networks, gesture monitoring, human-brain interfacing, digital twin applications, asset management, and universal coverage using non-terrestrial or aerial platforms, among other examples. As the demand for connectivity continues to increase, further improvements may be implemented, and other RATs, including 6G and beyond, may be introduced to enable new applications and use cases. The systems, methods, and devices described herein may enable one or more of the foregoing technologies or new technologies or support one or more of the foregoing use cases or new use cases.

Some wireless communication systems may use an analog-to-digital conversion (ADC) process to support wireless communications. This may include an ADC being implemented at each receive chain of a receiving device (e.g., a user equipment (UE)) that quantizes an input signal to convert the analog input signal to a digital signal or information for further decoding (e.g., at a baseband processor). The quantization process performed at the ADC generally includes the ADC evaluating the input signal against a reference level or value and using the comparison results to determine whether the input signal, at that time, corresponds to a “1” or a “0” (e.g., digital information). This process generally includes multiple steps where the input signal is compared to different reference values to detect and recover the digital information. However, this process is generally inefficient as the reference values are set or otherwise hardwired into the quantization portion of the ADC.

Aspects of the subject matter described in this disclosure relate to an enhanced successive approximation register (SAR)-ADC in each receive chain of a receiver device (e.g., a UE). For example, The SAR-ADC may generally apply a decision tree module using a known probability distribution function (PDF) associated with the input signal. The PDF implemented by the ADC during the quantization process may improve the reference values used to compare the input signal to reduce (e.g., increase efficiency) the number of comparisons used to detect and recover the digital information from the analog input signal. Generally, the PDF may be based on assistance information provided by the network (e.g., the network entity) to the UE which identifies or otherwise defines various characteristics of the input signal that has been propagated over the wireless channel as well as the noise plus interference.

For example, the network entity may transmit (and the UE may receive) a message that identifies the assistance information associated with the PDF. The PDF may generally correspond to a probability distribution of characteristics of input signals to be received by the UE over a wireless channel. The network entity may transmit (and the UE may receive) the input signal(s) via the wireless channel and the UE may quantize the input signal(s) received over the wireless channel. In some aspects, this may include quantizing the input signal by selecting one or more threshold values, one or more sequence orders, or both, during the ADC process that is based at least in part on the assistance information. In some aspects, the network entity may transmit the assistance information to the UE based on UE capability reporting from the UE that indicates support for using the assistance information.

Particular aspects of the subject matter described in this disclosure can be implemented to realize one or more of the following potential advantages. In some examples, by transmitting the assistance information associated with the PDF to the UE, the described techniques can be used to improve the receipt and recovery of the information being conveyed in the input signal(s). The signal transmitted by the network entity may be more efficiently and effectively recovered by the UE. Application of more accurate channel or interference measurement information via the assistance information may enable a more accurate estimation of the distribution probability of the input signals, which may enable reference values or levels to be initially selected to reduce the number of comparisons performed during the deciding process.

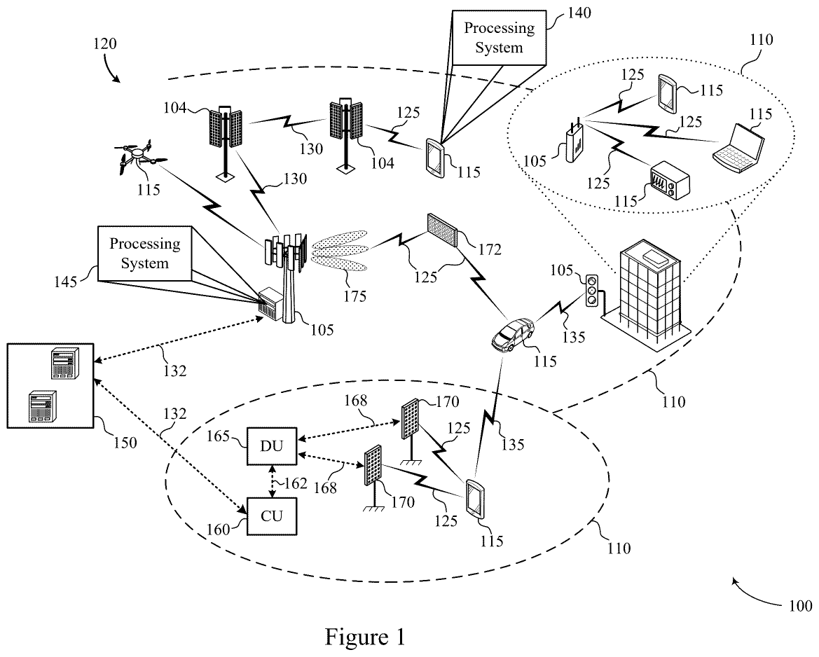

FIG. 1 shows an example of a wireless communication system 100. The wireless communication system 100 includes a core network 150 and a RAN 120 that support communication with one or more devices, such as UEs 115. A RAN 120 may include one or more network entities 105 configured to support wireless communication with the UEs 115.

The wireless communication system 100 may support communication among network entities 105 and UEs 115 in accordance with a layered protocol stack. For example, in a user plane, communication at a bearer layer, a Packet Data Convergence Protocol (PDCP) layer, or Service Data Adaption Protocol (SDAP) layer may be Internet Protocol (IP)-based. A Radio Link Control (RLC) layer may perform packet segmentation and reassembly to communicate via logical channels. A Medium Access Control (MAC) layer may perform priority handling and multiplexing of logical channels into transport channels. A MAC layer also may implement error detection techniques, error correction techniques, or retransmissions. In a control plane, a Radio Resource Control (RRC) layer may provide establishment, configuration, and maintenance of an RRC connection between UEs 115 and a network entity 105 or a core network 150, supporting radio bearers for user plane data. A Physical (PHY) layer may map transport channels to physical channels.

A core network 150 may support user authentication, access authorization, tracking, IP connectivity, and other access, routing, or mobility functions (such as via network entities 105). A core network 150 may be a 5G core (5GC) or 6G core (6GC), and may include at least one control plane entity that manages access and mobility and at least one user plane entity that routes packets or interconnects to external networks (such as a serving gateway (S-GW), a Packet Data Network (PDN) gateway (P-GW), a user plane function (UPF)).

A network entity 105 may support wireless communication in accordance with one or more coverage areas 110, and may be referred to as a network element, a network node, a RAN node, or network equipment, among other nomenclature. One or more of the network entities 105 may include or may be referred to as a base station. Depending on its capabilities, a base station may be referred to as a NodeB, an eNodeB (eNB), a next-generation NodeB or giga-NodeB (either of which may be referred to as a gNB), a 5G NB, a 6G NB, a next-generation eNB (ng-eNB), a Home NodeB, a Home eNodeB, or other suitable terminology. The wireless communication system 100 may include a heterogeneous network in which different types of network entities 105 support communication for one or more coverage areas 110 using the same or different RATs.

In some examples, a network entity 105 may be implemented in an aggregated (such as monolithic, standalone) architecture, which may utilize a protocol stack that is physically or logically integrated within one network entity 105 (such as a single physical RAN node). In some other examples, a network entity 105 may be implemented in a disaggregated architecture, which may utilize a protocol stack that is physically or logically distributed among multiple network entities 105, including in an integrated access and backhaul (IAB) network, an open RAN (O-RAN), or a virtualized RAN (vRAN). In a disaggregated architecture, a network entity 105 may include or be referred to as one or more of a central unit (CU) (such as CU 160), a distributed unit (DU) (such as DU 165), a radio unit (RU) (such as RU 170), or a combination thereof. The wireless communication system 100 may also implement a service-based architecture that provides a modular framework in which control plane functionality and common data repositories may be delivered through a set of interconnected network functions (NFs) that may access services of other NFs.

UEs 115 may be located in a coverage area 110 of one or more network entities 105 and may include or be referred to as an access terminal, a mobile station, a client device, or a subscriber unit. A UE 115 may be, include, or be coupled with a cellular phone, a wireless modem, a tablet device, a laptop computer, a wireless local loop (WLL) station, a camera, a medical or biometric device, a wearable device, a gaming device, an entertainment device, an XR device, a vehicular component or sensor, a smart meter or sensor, industrial manufacturing equipment, a Global Positioning System (GPS) or other positioning device, a robot or other device implementing artificial intelligence, a UE function of a network node, or any other wireless communication device or function that may communicate using a wireless medium.

The wireless communication system 100 may support various types of communication links among devices. For example, wireless communication between a network entity 105 and a UE 115 may be supported using one or more of a communication link 125 (such as a Uu interface), which may include downlink communication from a network entity 105 to a UE 115, uplink communication from a UE 115 to a network entity 105, or both. Direct wireless communication between UEs 115 may be supported using a communication link 135 (such as a device-to-device (D2D) communication link, a sidelink, a PC5 interface).

Communication between a network entity 105 and a core network 150 may be supported using a backhaul link 132 (such as an S1, N2, N3, NG, or other interface). In some implementations, communication between network entities 105 may be supported using a backhaul link 132 (such as an X2, Xn, or other interface) either directly (such as directly between network entities 105) or indirectly (such as via a core network 150). In some implementations (such as in a disaggregated architecture), communication between a CU 160 and a DU 165 may be supported using a midhaul link 162, and communication between a DU 165 and an RU may be supported using a fronthaul link 168. A backhaul link 132, a midhaul link 162, a fronthaul link 168, or any combination thereof may be or include one or more wired links (such as an electrical link, an optical fiber link) or one or more wireless links (such as a radio link, a wireless optical link), among other examples or combinations thereof. Wireless backhaul, midhaul, or fronthaul may be implemented via one or more IAB nodes 104, which may act as a relay using resources of an IAB donor network entity 105 (such as via a wireless link 130).

The wireless communication system 100 may include one or more of a relay 172 that may steer or reflect signals transmitted by other entities, which may support any of the described communication links. A relay 172 may include active elements or passive elements and may be in the form of a reconfigurable intelligent surface (RIS). An RIS may include tunable reflecting antenna arrays or metasurfaces, which may be used to enhance coverage or efficiency in multipath environments.

Network entities 105 and UEs 115 each may include one or multiple antennas. Multiple antennas of such devices may be used to employ techniques such as transmit diversity, receive diversity, MIMO communication, or beamforming, and may be organized or structured as one or more antenna panels, one or more antenna groups, one or more sets of antenna elements, or one or more antenna arrays, among other examples. As used herein, the term “antenna” may refer to one or more antennas, one or more antenna panels, one or more antenna groups, one or more sets of antenna elements, or one or more antenna arrays. The term “antenna panel” may refer to a group of antennas (such as antenna elements) arranged in an array or panel, which may facilitate beamforming by manipulating parameters associated with the group of antennas. In some implementations, an antenna panel may support RF beamforming for a signal transmitted or received via an antenna port. The term “antenna module” may refer to circuitry including one or more antennas as well as one or more other components (such as filters, amplifiers, processors, beamformers) associated with integrating the antenna module into a device such as a network entity 105 or a UE 115.

Beamforming, such as directional transmission or directional reception, is a signal processing technique that may be used at a transmitting device or a receiving device (such as at a network entity 105, at a UE 115) to shape or steer a beam 175 (such as an antenna beam, a transmit beam, a receive beam) along a spatial path (such as along a direction), which may include one or more paths between a transmitting device and a receiving device. Beamforming may be achieved by combining signals communicated via multiple antenna elements of an antenna array such that signals propagating along some orientations (such as relative to the antenna array) experience constructive interference while others may experience destructive interference. Adjustments of signals communicated via the antenna elements may include a transmitting device or a receiving device applying phase offsets, amplitude offsets, or other adjustments to signals carried via (such as transmitted by, received by) antenna elements of the device, which may be defined by a beamforming weight set associated with a particular orientation (such as relative to the antenna array of the device).

Communication resources of the wireless communication system 100 (such as of a RAN 120) may refer to a resource in the frequency domain (such as a frequency resource, an RF resource), a resource in the time domain (such as a time resource), a resource in the spatial domain (such as a spatial resource, a spatial layer), or a combination thereof. The wireless communication system 100 may leverage orthogonality of such resources to convey different communications to or from different devices (such as for a communication link 125, for a communication link 135, for unicast communication, for multicast communication, for broadcast communication).

A frequency resource may refer to a frequency or range of frequencies (such as a bandwidth, a frequency channel) of a frequency band implemented for wireless communication. For example, a frequency resource may refer to a resource of a lower frequency band (such as Frequency Range 1 (FR1), between 425 MHz and 7.125 GHz), a mid-band (such as Frequency Range 3 (FR3), between 7.125 GHz and 24.25 GHz), or an upper frequency band (such as Frequency Range 2 (FR2), between 24.25 GHz and 71 GHz). Communication in the upper frequency band may be referred to as millimeter wave (mmW) communication, and communication above an upper frequency band (such as between mmW and THz frequencies, between 100 GHz and 1 THz) may be referred to as sub-Terahertz (sub-THz) communication.

A frequency resource may refer to a “carrier” (such as a frequency channel), or portion thereof, and a carrier bandwidth may be referred to as a “system bandwidth.” A carrier may be subdivided in the frequency domain, including into subcarriers, bandwidth parts (BWPs), or both. For example, a resource block (RB), such as a physical resource block (PRB), may be defined in accordance with a set of subcarriers (such as twelve consecutive subcarriers in the frequency domain), and a BWP may be configured in accordance with a set of RBs (such as a set of contiguous RBs).

A frequency resource may be configured to carry either downlink communication or uplink communication (such as in a frequency division duplexing (FDD) configuration) or may be configured to carry both downlink and uplink communication (such as in a time division duplexing (TDD) configuration, in a sub-band full duplex (SBFD) configuration). One or more numerologies for a carrier may be supported, each associated with a subcarrier spacing (SCS) and a cyclic prefix (CP). Supported numerologies may vary by frequency range (such as FR1, FR2, FR3), and a carrier may be divided into portions (such as BWPs) having the same or different numerologies. BWPs may be configured as uplink BWPs or downlink BWPs (such as by a network entity 105), including in response to network conditions (such as to allocate uplink and downlink BWPs in response to traffic conditions), device capability (such as allocating BWPs with a greater quantity of RBs to UEs 115 with relatively higher capabilities), or both. A UE 115 may be configured with a set of multiple BWPs (such as a set of uplink BWPs, a set of downlink BWPs, or both), and a single BWP of a set (such as an active UL BWP, an active DL BWP, or both) may be active at a given time, such that communication of a UE 115 is supported by active BWP(s).

A time resource may refer to a duration of a frame (such as a radio frame, a frame structure), or portion thereof. For example, a frame may span a duration of 10 ms, and each frame may be identified by a system frame number (SFN). A frame may be subdivided in the time domain, including into subframes, slots, mini-slots, or a combination thereof. Slots or mini-slots may each include a respective quantity of symbols (such as symbol durations, symbol periods, OFDM symbols), which may be a function of a configured CP. A duration of a symbol is a function of the SCS or frequency band of operation.

A spatial resource may refer to an antenna, an antenna direction, an antenna port, a signal direction (such as a beamforming direction), or other resource that supports spatial orthogonality. A device (such as a network entity 105, a UE 115) may perform communications of a given frequency resource and time resource with a single spatial resource (such as communication without regard to spatial orthogonality). Additionally, or alternatively, a device may implement multiple spatial resources to support multiple signal streams using resources that are overlapping in the time and frequency domains (such as to support MIMO techniques).

Signals of the wireless communication system 100 (such as of a RAN 120) may be communicated using one or more resource elements (REs), and an RE may refer to a resource that corresponds to one subcarrier in the frequency domain and one symbol in the time domain. An RE may be used to convey a modulation symbol corresponding to one or more bits of information (such as of a physical channel, of a reference signal) in accordance with a modulation scheme. For example, a quadrature phase shift keying (QPSK) or quadrature amplitude modulation (QAM) technique may be implemented to communicate one or more bits that are distinguished in accordance with phase components, amplitude components, or both of a signal conveyed using a RE. A quantity of bits carried by an RE may depend on an order of the modulation scheme, and a relatively higher order may correspond to a relatively higher rate of communication. A device may support communication of REs using multiple subcarriers concurrently by implementing multi-carrier modulation (MCM) techniques such as orthogonal frequency division multiplexing (OFDM) or discrete Fourier transform spread OFDM (DFT-S-OFDM), among others.

Physical channels may carry information using modulation symbols conveyed by corresponding REs. Physical shared channels (such as for communicating user data) may include a physical downlink shared channel (PDSCH) for communicating user data in a downlink direction and a physical uplink shared channel (PUSCH) for communicating user data in an uplink direction. Physical control channels (such as for managing communication via physical channels) may include a physical downlink control channel (PDCCH) for communicating downlink control information (DCI) and a physical uplink control channel (PUCCH) for communicating uplink control information (UCI). A network entity 105 may indicate (such as schedule, allocate) communication resources for a UE 115 using DCI, including indicating downlink resources of a PDSCH (such as in accordance with a downlink grant), uplink resources of a PUSCH (such as in accordance with an uplink grant), or a combination thereof. A control region (such as a control resource set (CORESET)) for a physical control channel may be configured in accordance with a pattern of REs in the time and frequency domains, and one or more control regions may be configured for a set of UEs. A UE 115 may monitor control regions for control information according to one or more search space sets, which may include a common search space set (such as for sending control information to one or more UEs 115), UE-specific search space sets (such as for sending control information to a UE 115), or a combination thereof. A physical broadcast channel (PBCH) may be used to broadcast parameters to UEs 115 to synchronize with a network entity 105 and establish communications (such as to establish a communication link 125).

Reference signals may be communicated to establish reference characteristics (such as a frequency reference, a temporal reference, a spatial reference, a signal quality reference) between devices of a RAN 120, which may support communication using physical channels. Reference signals communicated between network entities 105 and UEs 115 may include synchronization signals (such as a primary synchronization signal (PSS), a secondary synchronization signal (SSS)) that support temporal synchronization, channel state information-reference signals (CSI-RSs) that support evaluating downlink channel characteristics, sounding reference signals (SRSs) that support evaluating uplink channel characteristics, demodulation reference signals (DMRSs) that support demodulation, or phase tracking reference signals (PTRSs) for evaluating oscillator characteristics, among others. Network entities 105 and UEs 115 may receive and measure transmitted reference signals to support one or more of these and other functions.

Devices of the wireless communication system 100 may be configured to support one or more aspects of the described techniques for network assistance and trigger based reporting for energy efficient quantization. For example, a UE 115 may include a processing system 140, and a network entity 105 may include a processing system 145, each of which may be configured to cause the respective device to perform (such as being configured as means for performing) one or more of the described operations. By configuring a processing system 140, a processing system 145, or a combination thereof in accordance with the described techniques, the wireless communication system 100 (such as the RAN 120) may support improved decoding operations that are more efficient based on a more accurate and timely understanding of the channel conditions over which the inputs signal(s) are conveyed.

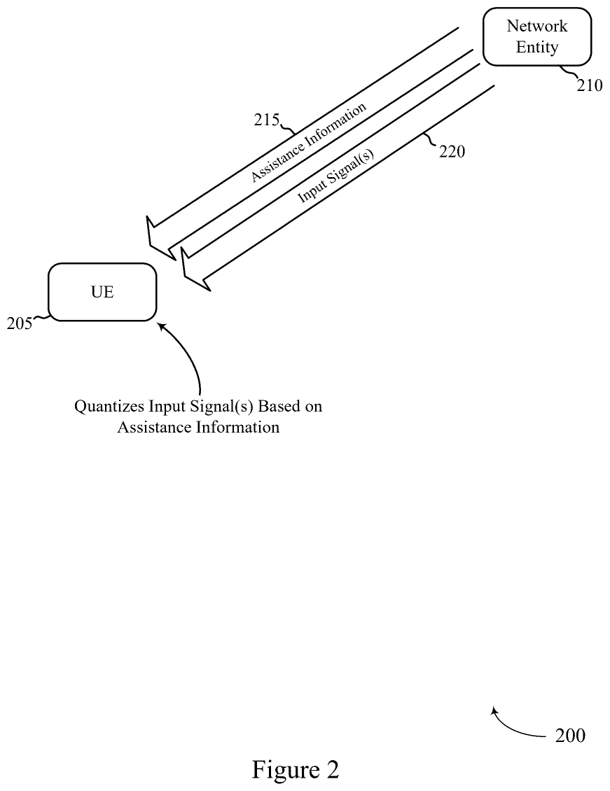

FIG. 2 shows an example of a signaling diagram 200 that supports network assistance and trigger based reporting for energy efficient quantization. Aspects of the signaling diagram 200 may implement aspects of and/or may be implemented by aspects of the wireless communication system 100. Aspects of the signaling diagram 200 may be implemented at and/or implemented by a UE 205 and a network entity 210, which may be examples of the corresponding devices described herein.

A wireless device (e.g., the UE 205) may support two or more operating modes for wireless communications for its transmitter and/or its receiver. One mode may include a digital-dominant mode which has a larger number of radio frequency (RF) chains active and offers a larger number of ports. This mode allows for achieving finer beams (e.g., improved spherical coverage, coherent combining of multiple paths etc.) and better communication link quality, but also results in increased UE power consumption. Another mode may include an analog-dominant mode which has a fewer number of RF-chains active offering a fewer number of ports. This mode may allow for achieving reduced UE power consumption, but also results in coarser beams (e.g., reduced spherical coverage, more unidirectional beams, etc.) and lower communication link quality.

In some aspects, each RF chain may house or otherwise include a pair of ADCs. An interface may transfer the quantized outputs of the ADC to the baseband for further processing and decoding. A range of mode options (e.g., offering varying number(s) of ports and varying levels of constraints on realizable spatial domain filter(s)) that trade communications link quality and consumed power can be available at the UE 205, in some examples. As part of network entity efficient scheduling, a UE may be expected to receive and buffer a large bandwidth allocation within a short burst period. This may make the reduction of energy consumed in quantization a meaningful issue in such cases. The quantized outputs must also be efficiently transferred to the baseband for further processing and decoding.

The ADC may also be referred to as a SAR-ADC that has an associated flow or process of operations. A first step may include the analog input voltage being held on a track/hold. To implement the binary search algorithm (e.g., the quantization process), an N-bit register may be first set to a midscale value (that is, 100 . . . 0.00, where the MSB is set to 1). This generally forces a digital-to-analog converter (DAC) output (VDAC) to be VREF/2, where VREF is the reference voltage provided to the ADC. A comparison may then be performed to determine if Vᵢₙ is less than, or greater than, V_{dac}. If Vᵢₙ is greater than V_{dac}, the comparator output is a logic high, or “1,” and the MSB of the N-bit register may remain at 1. Conversely, if Vᵢₙ is less than V_{dac}, the comparator output is a logic low and the MSB of the register is cleared to logic 0. The SAR-ADC control logic then moves to the next bit down, forces that bit high, and does another comparison. This sequence continues all the way down to the LSB. Once this is completed, the conversion is complete (e.g., the input signal has been quantized), and the N-bit digital word is available in the register.

An effective number of bits (ENOB) may be used for the cases of a small or mid-sized bandwidths and is usually not an issue. This may become an issue for large bandwidth cases, among others, due to the integral non-linearity/differential non-linearity (INL/DNL) impairments. In some wireless networks, the SAR thresholds (e.g., the threshold values) are conventionally chosen based on assuming a uniform distribution of the input signal. This may result in the ADC/quantization processing of the input signal being inefficient.

For example, given a variable z∈[−1,7] with a known PDF of Pr(5≤z≤7)=½; Pr(3≤z≤5)=¼; Pr(1≤z≤3)=⅛; Pr(−1≤z≤1)=⅛ and application of such techniques may result in a quantized output of y=Q (z); Using 2 bits and uniform quantization labels {0;2;4;6} and such a standard SAR-ADC approach, the quantized y=Q(z) can be obtained using two comparison cycles per-quantization adopting this decision tree.

However, the techniques discussed herein generally provide for an enhanced SAR-ADC that utilizes a maximum entropy reduction decision tree that uses a known input PDF. This approach may carefully choose the comparison thresholds and/or sequence orders based on the input signal PDF and/or probability mass function (PMF). As one example, for a channel with a Gaussian desired signal and a mixture Gaussian interference, the described techniques may use a known variance of the desired and the interfering signals as well as interference mode likelihood. This approach may result in a significant (e.g., over 40%) reduction in the average number of comparison cycles for enhanced SAR-ADC compared to baseline SAR-ADC. Using the example described above, the described techniques may reduce the average number of comparisons from two to 1.75. Reducing the average number of comparisons directly translates to a reduction in energy consumption as well as the average latency.

For example, aspects of the techniques described herein may provide for the network to configure and provide assistance information to the UE 205 based on which it can determine or estimate a PDF modeling distribution of an input signal to at-least one SAR-ADC. For example, at 215 the network entity 210 may transmit or otherwise output (and the UE 205 may receive or otherwise obtain) a message that carries or otherwise conveys assistance information associated with a PDF. The assistance information may be associated with the PDF based on various information related to the channel performance characteristics indicated in the assistance information. For example, the PDF may correspond to or otherwise be associated with a probability distribution of characteristics of input signals to be received by the UE 205 over the wireless channel. At 220, the network entity 210 may transmit or otherwise output (and the UE 205 may receive or otherwise obtain) various input signal(s) over the wireless channel.

In some aspects, the PDF determined according to or otherwise based on the assistance information may provide a probability distribution that can be of a normalized (e.g., scaled) input signal seen at an ADC housed on any RF-chain in the UE 205. The input signal may be some analog signal which the UE 205 is to digitize or quantize (such as sampled received observation, etc.). In some cases, the assistance information may be statistical information corresponding to the probability distribution across a spatial domain and/or across a time domain. For example, the assistance information can be specified as statistical information to be used towards modeling the distribution of the transmitted waveform (e.g., across spatial domain at any time snapshot and/or across time samples at any spatial dimension). In some cases, the assistance information may be specified as statistical information for modeling distribution of predicted interference plus noise, among other impairments. In each case, as an example, the Gaussian mixture (e.g., with parameters such as number of modes, their ratio of peak to RMS, likelihood, etc.) can be used to model the distribution of the input signal according to the PDF. For example, the UE 205 may generate the PDF based on the assistance information provided by the network entity 210.

In some cases, the assistance information may be indexed by location (e.g., on a location basis) and/or frequency band (e.g., on a frequency band basis). In some cases, the assistance information may be refined in a crowd-sourcing fashion by the network entity 210. For example, the network entity 210 may collect various channel condition feedback reports from UEs communicating with the network entity 210 and use this information to generate the channel performance model (e.g., the PDF) that is provided to the UE 205.

In some cases, the assistance information may be accompanied with a validity time-period information (e.g., a time period during which the probability distribution is valid)). For example, the UE 205 may be informed about the start-time and/or the end-time for the assistance information to be valid. In some cases, the assistance information may be based on prediction by the network. For example, the network entity 210 may predict the assistance information to be provided to the UE 205 based on historical communication states or direction, channel performance metrics, among other factors or considerations. In some cases, the assistance information may be UE-specific being based on UE location, velocity and specific aspects of the UE's transceiver that the network has determined from transmissions, receptions, and/or other feedback associated with the UE 205 in the past. In some cases, the assistance information can also be exchanged (e.g., fully or partially) among UEs, such as over a sidelink interface.

In some cases, the network can also provide more light-weight assistance information to the UE 205. For example, the network entity 210 may indicate that the interference profile observed by the UE 205 will not change for an indicated time-frequency span (e.g., a time period and/or frequency span during/within which the probability distribution is valid). This approach may allow the UE 205 to combine and apply its own learning algorithm or model about the interference statistics and/or distribution over the whole indicated time-frequency span.

In some cases, the network may proactively instruct the UE 205 to measure and assess the interference statistics and/or distribution over a measurement resource. For example, the assistance information provided to the UE 205 may include a measurement request where the network entity 210 transmits (and the UE 205 measures) reference signal(s) over measurement resources identified in the assistance information. For example, the UE 205 may perform a channel measurement via the measurement resources identified in the assistance information. For example, the measurement resources may be an interference measurement resource for which a specialized indication to further assess the interference statistics and/or distribution is also made. In some cases, a TimeRestrictionForInterferenceStatisticsMeasurement field or information element (IE) can be indicated to the UE 205 (e.g., in the assistance information) to convey the time-period over which the measurement would also be suitable for further interference statistics and/or distribution assessment by UE 205. For instance, utilizing its enhanced SAR-ADC outputs can provide the UE 205 with more nuanced information about the interference distribution as opposed to just a covariance estimation.

In some cases, the network may be aware of UE ability from its capability report and can configure such measurement. For example, the UE 205 may transmit or otherwise output (and the network entity 210 may receive or otherwise obtain) a UE capability report that indicates support (e.g., by the UE 205) for using the assistance information during quantizing the input signal(s). For instance, when the network entity 210 knows that there will be a dominant relatively stable interference impacting the UE 205, this can arise for a UE paired and/or co-scheduled with another fixed wireless access (FWA) UE or device. Accordingly, the UE 205 may benefit by trying to learn and exploit the interference distribution instead of just using covariance information. Additionally, or conversely, the network entity 210 may also indicate that the interference at the UE 205 is likely to vary significantly. In this case, the UE 205 may revert to using its default ADC settings assuming uniform or some (pre)configured default distribution for the input signal.

In some cases, the described techniques may include the UE 205 feeding back information to the network entity 210. For example, the UE 205 may transmit or otherwise output (and the network entity 210 may receive or otherwise obtain) an update message that confirms and/or modifies one or more parameters of the assistance information based on a result of the UE 205 quantizing the input signal. For example, the UE 205 may also report its refinement to the assistance information back to the network. The refinement information provided in the update message may, for instance, be based on the PDF determined at each ADC using the quantized outputs (e.g., specifically by the decision tree module). In some cases, the update message may be transmitted to the network entity 210 based on the occurrence of a trigger condition associated with the accuracy level observed during quantizing the input signal based on the assistance information. For example, the update message may be provided to the network entity 210 based upon some configured trigger conditions. In some cases, the update message may be provided to the network entity 210 based upon a network request (e.g., in an aperiodic, periodic, and/or semi-persistent manner).

In some cases, the trigger event observed by the UE 205 reporting the update message to the network entity 210 may be based on a reliable estimate of the input signal PDF (e.g., based on the quantized outputs) being available to the DEM module. In some cases, this PDF may be significantly different from the input PDF determined by the UE 205 solely using network provided assistance information. One difference in the distributions can be, for instance, the measured and/or characterized PDF via Kullback Leibler divergence.

Accordingly, the UE 205 may receive the input signal(s) over the wireless channel and quantize the input signal according to the assistance information. For example, the UE 205 may use the assistance information to select or otherwise define threshold value(s) and/or sequence order(s) during the ADC process based on the assistance information. This approach may reduce the number of comparisons by selecting threshold values and/or sequence orders applied during the ADC process using the PDF that more dynamically or accurately maps the interference and/or signal distribution of the signal observed from the wireless channel.

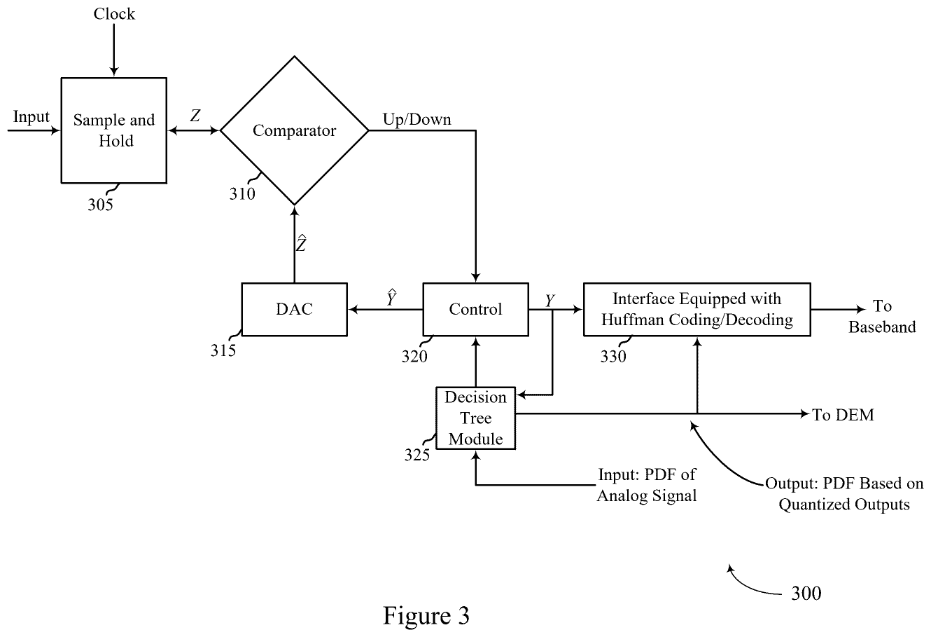

FIG. 3 shows an example of an ADC configuration 300 that supports network assistance and trigger based reporting for energy efficient quantization. Aspects of the ADC configuration 300 may implement aspects of and/or be implemented by aspects of the wireless communication system 100 and/or the signaling diagram 200. Aspects of the ADC configuration 300 may be implemented at and/or implemented by a UE, which may be an example of the corresponding device described herein. In some cases, the UE may include one ADC configuration 300 for each receive chain of the UE.

As discussed above, aspects of the techniques described herein provide for network provided assistance information that may be based on or otherwise associated with a PDF that corresponds to a probability distribution of characteristics of input signals to be received by a UE over a wireless channel. The assistance information provided to the UE may be used to generate or otherwise identify the PDF corresponding to the probability distribution of the signal transmitted by the transmitter and/or the interference seen over the wireless channel. The UE may use the assistance information (e.g., the PDF) while quantizing the input signal by selecting or otherwise identifying threshold value(s) and/or sequence orders during an ADC process. The ADC configuration 300 illustrates an example where the UE may perform the ADC process to quantize the input signals. As discussed, one or more instances of the ADC configuration 300 may be implemented at and/or implemented by the UE, such as one ADC configuration 300 per receive chain of the UE.

For example, the input signal received over the wireless channel may be provided as an input to, along with a clock input, the sample and hold 305. The sample and hold 305 may generally capture and hold a sample of the input signal (e.g., using one or more buffers or other memory devices and/or functions). The output of the sample and hold 305 (e.g., Z) may be provided as an input to the comparator 310. The comparator 310 may receive the Z input from the sample and hold 305 and compare it to a threshold value (e.g., \hat{Z}) provided by a DAC 315. The comparator 310 may compare both inputs and determine whether the Z input is higher than or less than the threshold value and provide an output of either up (e.g., “1”) or down (e.g., “0”) to the control module 320. The control module 320 may accepts an input from the decision tree module 325 that includes the PDF/PMF of the analog signal (which is being quantized by the ADC configuration 300) and build a decision tree based on that information. For example, the input to the decision tree module 325 may include the PDF of the input signal obtained from the network entity (e.g., the PDF associated with or otherwise indicated by the assistance information). The output of the decision tree module 325 may include an updated PDF/PMF that is based on the quantized outputs (e.g., as provided by the control module 320).

For example, the decision tree module 325 may adapt the comparator thresholds to maximally reduce conditional entropy, subject to the knowledge of the input signal distribution (considering the interference and/or other impairments). By using the input signal distribution, the decision tree module 325 may set the SAR-ADC comparison thresholds (e.g., threshold values), which reduces the average number of comparisons needed for best quantization under given quantization labels. Since quantization labels are not changed (i.e., uniform quantization is retained), the downstream signal-processing blocks do not have to change. An updated PDF can be estimated based on the quantized outputs. This updated PDF can be reported to the distribution estimator (DEM) module for refinement of the input signal PDF. The updated PDF can also be used to efficiently transfer the quantized samples (bits) to the baseband via an enhanced interface (e.g., the interface 330) equipped with Huffman coding/de-coding blocks, for example. In some cases, a special value input to the decision tree module 325 can indicate that the PDF of the analog input signal is unavailable. In this case the decision tree module 325 may revert to default or baseline SAR-ADC comparator thresholds.

For higher quantization resolution and when sufficient number of quantized outputs are available, the decision tree module can obtain an estimate of input signal pdf based on quantized outputs. This estimated pdf can be provided as output. In other cases, a special value of output can indicate that no such pdf can be computed.

The output (Y) of the control module 320 is provided to the interface 330 as well as being fed back to the decision tree module 325. The interface 330 may efficiently transfer bits to the baseband module (e.g., via Huffman coding/de-coding) using the quantized outputs based PDF (e.g., the updated PDF). Some interfaces may not exploit such PDF signaling and can become a bottleneck since no compression of the transferred bits can be achieved.

Accordingly, the decision tree module 325 may provide an input to the control module 320 that updates the threshold values and/or the sequence orders (e.g., the order of sequences that the input signal is compared to). The control module 320 may use this information and provide an output (e.g., Y) to the DAC 315 which changes the threshold values being used by the comparator 310 to evaluate the analog input signals. This process may repeat until the input signal has been quantized by the ADC configuration 300. Any updates to the PDF/PMF determined by the decision tree module 325 based on the quantized outputs provided by the control module 320 may be provided to the DEM by the decision tree module 325 as well as being provided to the baseband by the interface 330 for further processing and decoding.

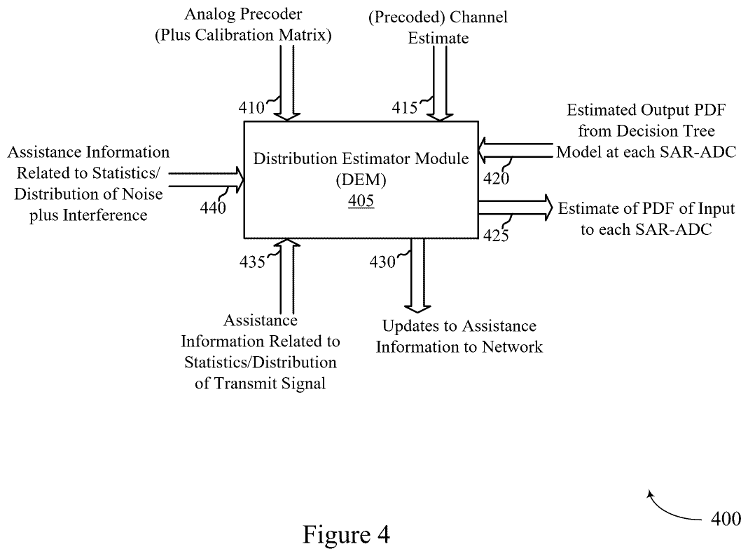

FIG. 4 shows an example of a DEM configuration 400 that supports network assistance and trigger based reporting for energy efficient quantization. Aspects of the DEM configuration 400 may implement aspects of and/or be implemented by aspects of the wireless communication system 100, the signaling diagram 200, and/or the ADC configuration 300. Aspects of the DEM configuration 400 may be implemented at and/or implemented by a DEM 405 implemented by or at a UE, which may be an example of the corresponding device described herein. In some cases, the UE may include one or more of the DEM 405. For example, the DEM 405 may be implemented in a UE in operative communications with each ADC configuration (e.g., SAR-ADC) of the UE.

As discussed above, aspects of the techniques described herein provide for network provided assistance information that may be based on or otherwise associated with a PDF that corresponds to a probability distribution of characteristics of input signals to be received by a UE over a wireless channel. The assistance information provided to the UE may be used to generate or otherwise identify the PDF corresponding to the probability distribution of the signals associated with the wireless channel. The UE may use the assistance information (e.g., the PDF) while quantizing the input signal by selecting or otherwise identifying threshold value(s) and/or sequence orders during an ADC process. The DEM 405 illustrates an example where each ADC process may be performed by the UE to quantize the input signals and the PDF/PMF initially used and/or updated by the ADCs are coordinated by the DEM 400. For example, the DEM 405 may include numerous inputs and/or outputs that may manage aspects of the quantization processes being performed by the ADC configurations at each receive chain of the UE.

At 410, the DEM 405 may obtain as an input the analog precoder information as well as the calibration matrix information. The analog precoder information may be used to identify or otherwise determine the precoding matrix associated with the analog input signal. At 415, the DEM 405 may obtain as an input the (precoded) channel estimate. The (precoded) channel estimate may include various information regarding the channel performance characteristics associated with the input signal (e.g., combination or product of one or more of: channel estimate matrix and a precoder matrix and a calibration matrix, as reference signal received power (RSRP), signal-to-noise interference ratio (SINR), and the like).

At 420, the DEM 405 may obtain as an input the estimated output PDF from decision tree models at each SAR-ADC (e.g., as discussed with reference to FIG. 3). At 425, the DEM 405 may provide as an output an estimate of the PDF of input to each SAR-ADC. For example, the DEM 405 may provide updates to the PDF to be used by each SAR-ADC during the quantization process for the input signal. The updates may be based on various updates to the parameter(s) of the PDF obtained by decision tree models at each SAR-ADC.

At 430, the DEM 405 may provide as an output an update to the assistance information to the network. For example, the DEM 405 may manage aspects of transmitting one or more update messages to the network entity to update the assistance information being provided to the UE. At 435, the DEM 405 may obtain as an input the assistance information related to the statistics and/or distribution of the transmitted signal (e.g., the PDF of the input signal).

At 440, the DEM 405 may obtain as an input the assistance information related to the statistics and/or distribution of the noise plus interference. That is, the portion of the assistance information related to the noise or other interference associated with the wireless channel.

As one example, the network assistance information may be used to model the distribution of input signals to each SAR-ADC of the UE. The model distribution may be determined according to z=W*u=W*(Hs+n), where u is the received observation pre-analog combining, W is the analog precoder used by device, H Channel matrix estimated by device, s is the signal transmitted by the network entity, and n is the noise-plus-interference-plus-impairments.

For analog-dominant mode, the observations may be received across ports post receive combining may be or have a lower dimensional, where the converse holds for digital dominant mode. In case of rank-1 analog-beamforming, only scalar quantization may be needed. Other cases may benefit from quantization exploiting the correlations across inputs.

In the case where the channel estimate or any other assistance information inputs are unavailable, via a special value of its PDF output, the DEM 405 may indicate to each SAR-ADC to use default settings. In some examples, the DEM 405 may provide a marginal PDF as input to each ADC. This may allow for parallel quantization processes by all SAR-ADCs but does not exploit correlations across these inputs. In some examples, the DEM 405 may provide a conditional PDF as input to each ADC. This can exploit correlations across inputs but can introduce latency since the quantization processes are performed sequentially.

In some cases, the PDFs may be provided to the SAR-ADC in a grouped fashion. That is, different approaches may be provided for using the network provided assistance information to provide input distribution to each SAR-ADC. These approaches may be based on the quantization of K analog variables {z₁, z₂, . . . , z_{K}}.

A scalar approach may include determining marginal PDFs {Pr(z₁), Pr(z₂), . . . , Pr(z_{K})} using the network provided assistance information. This may also include the SAR-ADC individually applying scalar quantization using the marginal PDFs {Pr(z₁), Pr(z₂), . . . , Pr(z_{K})}. This approach may not exploit correlations among these variables but may allow for parallel quantization with low latency.

A sequential vector quantization approach may include determining a joint PDF {Pr(z₁, z₂, . . . , z_{K})} using the network provided assistance information. For the kₜₕ ADC, the decision tree may be built using the conditional PDF Pr(zₖ|zₖ₋₁, zₖ₋₂, . . . , z₁) along with previous k−1 SAR-ADC outputs. This approach may exploit the correlation across input variables. The direct application of this joint PDF/PMF approach may include building decision trees using these conditional PDFs.

A truncation approach may include, at stage k, using a truncated PDF Pr(zₖ|zₖ₋₁) instead of pdf Pr(zₖ|zₖ₋₁, zₖ₋₂, . . . , z₁). Additionally, or optionally, this may include removing conditional mean of the remaining variables {zₖ₋₂, . . . , z₁}. This approach may improve scalability concerns.

A parallel group quantization strategy may also be applied in some examples. This may include partitioning {1, 2, . . . , K} into L group {G₁, G₂, . . . , G_{L}}, where the grouping rule can exploit the estimated joint PDF. The joint distribution of the variables within each group may be used where these are marginalized across groups. The quantization across the groups

$${\{ {G}_{k} \}}_{k = 1}^{L}$$

may be performed in parallel by the SAR-ADCs. Within each group, a truncation may applied based on the sequential quantization approach. This approach can balance scalability and latency with performance.

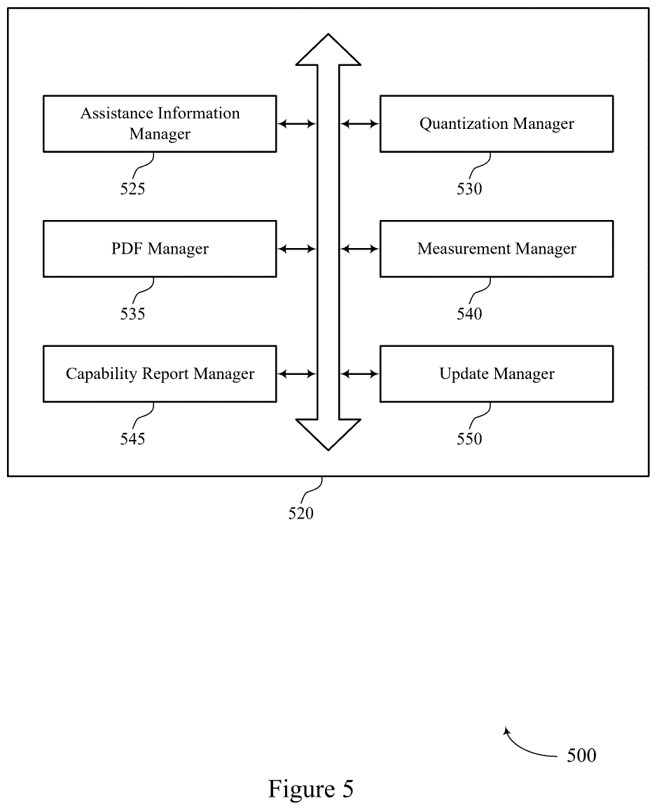

FIG. 5 shows an example of a processing system 520 that supports network assistance and trigger based reporting for energy efficient quantization. A processing system 520 may be an example of a processing system 140 (such as of a UE 115) and may include an assistance information manager 525, a quantization manager 530, a PDF manager 535, a measurement manager 540, a capability report manager 545, an update manager 550, or any combination thereof. A processing system 520, or various component thereof, may be an example of means for performing (such as a means for causing a UE 115 to perform) various techniques described herein.

The assistance information manager 525 may be configured to cause the UE 115 to receive a message that identifies assistance information associated with a PDF, the PDF corresponding to a probability distribution of characteristics of input signals to be received by the UE over a wireless channel. The quantization manager 530 may be configured to cause the UE 115 to quantize an input signal received over the wireless channel, where quantizing the input signal includes selecting one or more threshold values, one or more sequence orders, or both, during an ADC process that is based on the assistance information. In some examples, the assistance information includes statistical information corresponding to the probability distribution across a spatial domain, across a time domain, or both.

In some examples, the PDF manager 535 may be configured to cause the UE 115 to generate the PDF based on the assistance information. In some examples, the assistance information is on a location basis, a frequency band basis, a time period basis, or any combination thereof. In some examples, the assistance information includes a time period during which the probability distribution is valid, a frequency span within which the probability distribution is valid, or both.

In some examples where the assistance information includes a measurement request, the measurement manager 540 may be configured to cause the UE 115 to perform a channel measurement via a measurement resource identified in the assistance information, where quantizing the input signal is based on a result of the channel measurement.

In some examples, the capability report manager 545 may be configured to cause the UE 115 to transmit a UE capability report that indicates support for using the assistance information during quantizing the input signal, where the message is received based on the UE capability report.

In some examples, the update manager 550 may be configured to cause the UE 115 to transmit an update message that confirms or modifies one or more parameters of the assistance information based on a result of quantizing the input signal. In some examples, the update message is transmitted based on an occurrence of a trigger condition associated with an accuracy level observed during quantizing the input signal that is based on the assistance information.

A processing system 520 may include or be a component of one or more chips, systems-on-chips (SoCs), chipsets, packages, components, or devices that individually or collectively constitute or include a processing system. A processing system 520 may interface with other components of a processing system 520. For example, operations described with reference to a processing system 520, or various components thereof, may be performed by or with other such components, including a receiver, a transmitter, a transceiver, a modem, a user interface, a modulator/demodulator, an encoder/decoder, or any combination thereof (such as of the processing system 520, coupled with the processing system 520, of a processing system 520).

By including or configuring a processing system 520 for operation in a processing system 520 as described herein, the processing system 520 may support techniques for improved decoding operations at a receiving device (e.g., a UE 115) by leveraging assistance information provided by the network relating to the wireless channel to more efficiently perform quantization of the input signal(s).

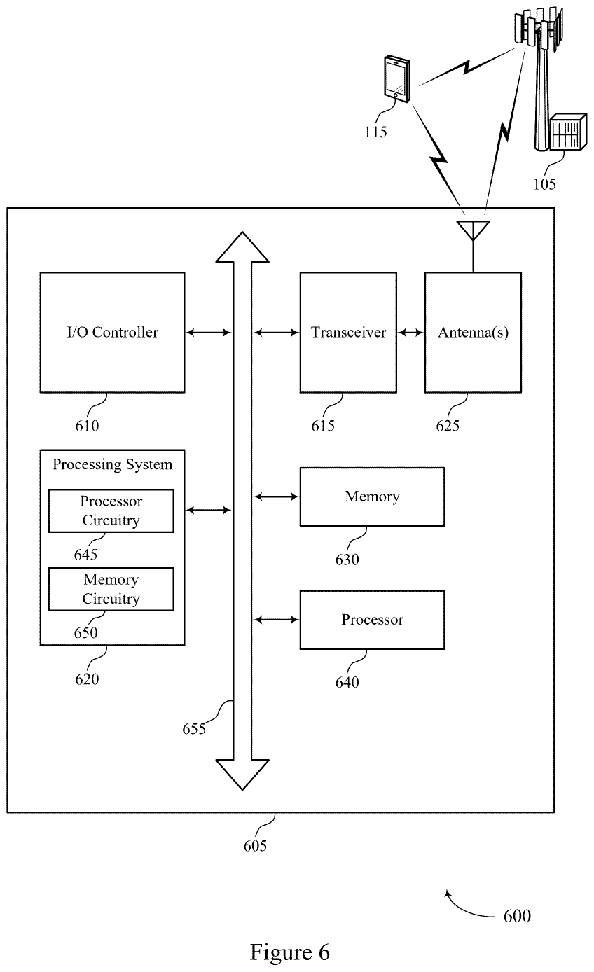

FIG. 6 shows an example of a system 600 including a device 605 that supports network assistance and trigger based reporting for energy efficient quantization. The device 605 may be an example of or include components of UE 115. The device 605 may communicate (such as wirelessly) with one or more other devices (such as network entities 105, UEs 115). The device 605 may include components for transmitting and receiving communication, which may include a processing system 620, an input/output (I/O) controller, such as an I/O controller 610, a transceiver 615, antenna(s) 625, a memory 630, and a processor 640. Components of the device 605 may be coupled (such as operatively, communicatively, functionally, electronically, electrically, in electronic communication) a bus 655.

The transceiver 615 may support bi-directional communication via antenna(s) 625, and may support transmission operations, reception operations, or both, as described herein. The transceiver 615 may implement functionality of a modem (such as a wireless modem) and may include one or more RF chains. An RF chain may include one or more filters, mixers, oscillators, amplifiers, analog-to-digital converters (ADCs), and other components that convert between an analog signal (such as for transmission or reception via an air interface) and a digital signal (such as for digital processing at the device 605). The transceiver 615 may modulate symbols and provide the modulated symbols to antenna(s) 625 for transmission, and demodulate symbols from signals received using antenna(s) 625.

The processor 640 may be a general-purpose processing component that supports various operations (such as applications) of the device 605. The memory 630 may be a general-purpose storage component that stores code executable by the processor 640. Such code may include instructions that, when executed by the processor 640, cause the device 605 to perform various functions (such as to support an application of the device 605). The I/O controller 610 may manage inputs and outputs for the device 605, may manage peripherals not integrated into the device 605, or may represent a physical connection (such as port) to an external peripheral. The processor 640 may interact with a modem, a keyboard, a mouse, a touchscreen, or other device (such as via I/O controller 610). In some implementations, a user may interact with the device 605 via the I/O controller 610 or via hardware components controlled by the I/O controller 610.

The processing system 620 may be an example of a processing system 140 or a processing system 500. For example, the processing system 620 may include processor circuitry 645 and memory circuitry 650 that stores code, and may be configured to cause the device 605 to perform operations that support network assistance and trigger based reporting for energy efficient quantization. Although the processing system 620 is illustrated as a separate component, which may involve a separate chip, chipset, or other module, in some implementations, one or more functions described with reference to the processing system 620 may be supported by or performed by a transceiver 615, antenna(s) 625, a processor 640, memory 630, or any combination thereof, such that a processing system 620 may include one or more of a transceiver 615, antenna(s) 625, a processor 640, memory 630, or any combination thereof.

By including or configuring the processing system 620 for operation in the device 605 as described herein, may support techniques for improved decoding operations at a receiving device (e.g., a UE 115) by leveraging assistance information provided by the network relating to the wireless channel to more efficiently perform quantization of the input signal(s).

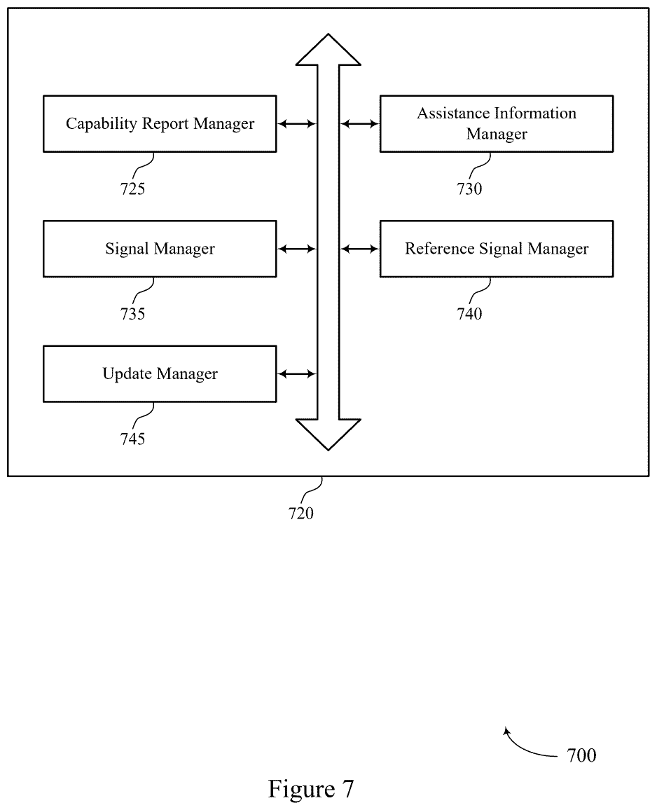

FIG. 7 shows an example of a processing system 720 that supports network assistance and trigger based reporting for energy efficient quantization. A processing system 720 may be an example of a processing system 145 (such as network entity 105) and may include a capability report manager 725, an assistance information manager 730, a signal manager 735, a reference signal manager 740, an update manager 745, or any combination thereof. A processing system 720, or various component thereof, may be an example of means for performing (such as a means for causing a network entity 105 to perform) various techniques described herein.

The capability report manager 725 may be configured to cause the network entity 105 to receive a UE capability report that indicates support by a UE for using assistance information during quantizing an input signal. The assistance information manager 730 may be configured to cause the network entity 105 to transmit, to the UE and based on the UE capability report, a message that identifies assistance information associated with a PDF, the PDF corresponding to a probability distribution of characteristics of input signals to be received by the UE over a wireless channel. The signal manager 735 may be configured to cause the network entity 105 to transmit an input signal to the UE over the wireless channel, where the UE quantizes the input signal by selecting one or more threshold values, one or more sequence orders, or both, during an ADC process that is based on the assistance information.

In some examples, the assistance information includes statistical information corresponding to the probability distribution across a spatial domain, across a time domain, or both. In some examples, the assistance information is on a location basis, a frequency band basis, a time period basis, or any combination thereof. In some examples, the assistance information includes a time period during which the probability distribution is valid, a frequency span within which the probability distribution is valid, or both.

In some examples where the assistance information includes a measurement request, the reference signal manager 740 may be configured to cause the network entity 105 to transmit, to the UE, a reference signal for a channel measurement via a measurement resource identified in the assistance information.

In some examples, the update manager 745 may be configured to cause the network entity 105 to receive, from the UE, an update message that confirms or modifies one or more parameters of the assistance information based on a result of quantizing the input signal. In some examples, the update message is transmitted based on an occurrence of a trigger condition associated with an accuracy level observed during quantizing the input signal that is based on the assistance information.

A processing system 720 may include or be an example of one or more chips, SoCs, chipsets, packages, components, or devices that individually or collectively constitute or include a processing system. A processing system 720 may interface with other components of a network entity 105. For example, operations described with reference to a processing system 720, or various components thereof, may be performed by or with other such components, including a receiver, a transmitter, a transceiver, a modem, a user interface, a modulator/demodulator, an encoder/decoder, or any combination thereof (such as of the processing system 720, coupled with the processing system 720, of a network entity 105). Operations described herein with reference to the processing system 720, or various components thereof, may be performed by or with other such components, including a CU 160, a DU 165, an RU 170, or any combination thereof. Each of one or more of any of such components, or subcomponents thereof (such as one or more processors, one or more memories), may communicate, directly or indirectly, with one another. The communication may include communication within a protocol layer of a protocol stack, communication associated with a logical channel of a protocol stack (such as between protocol layers of a protocol stack, within a device, component, or virtualized component associated with a network entity 105, between devices, components, or virtualized components associated with a network entity 105), or any combination thereof.

By including or configuring a processing system 720 for operation in a processing system 720 as described herein, the processing system 720 may support techniques for improved decoding operations at a receiving device (e.g., a UE 115) by leveraging assistance information provided by the network relating to the wireless channel to more efficiently perform quantization of the input signal(s).

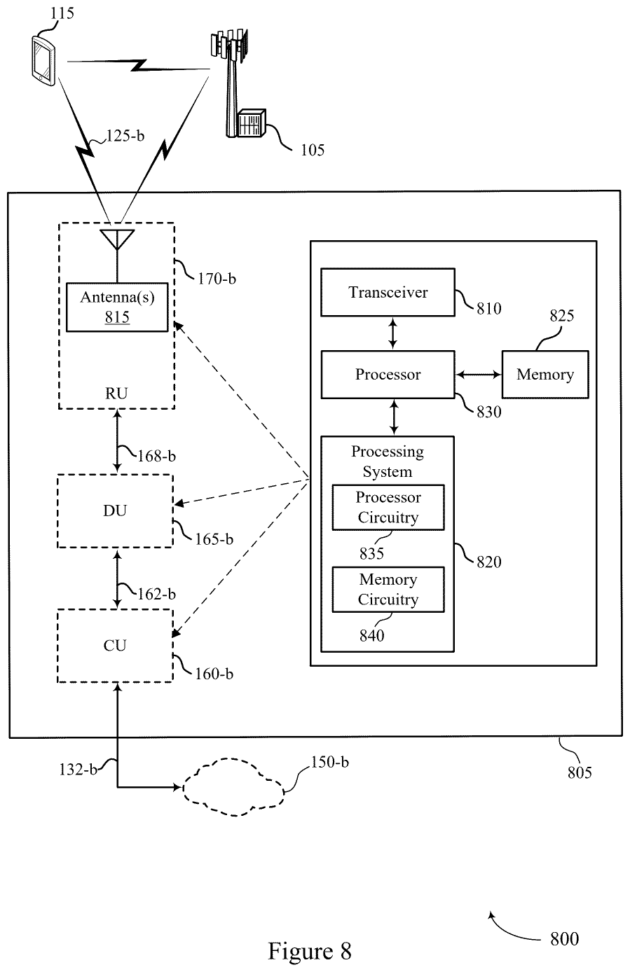

FIG. 8 shows an example of a system 800 including a device 805 that supports network assistance and trigger based reporting for energy efficient quantization. The device 805 may communicate (such as via one or more wired interfaces or one or more wireless interfaces) with other network devices or network equipment such as a core network 150-b, other network entities 105, UEs 115, or any combination thereof. The device 805 may include components for transmitting and receiving communication, which may include a processing system 820, a transceiver 810, antenna(s) 815, a memory 825, and a processor 830. Components of the device 805 may be coupled (such as operatively, communicatively, functionally, electronically, electrically, in electronic communication) via one or more interfaces.

The transceiver 810 may communicate bi-directionally with another transceiver via wired or wireless links, and may support transmission operations, reception operations, or both, as described herein. The transceiver 810 may include a modem to modulate and demodulate signals, to provide the modulated signals for transmission (such as via antenna(s) 815, via a wired interface), and to demodulate received signals (such as received via antenna(s) 815, received via a wired interface). The transceiver 810 may be operable to support communication via one or more communication links (such as a communication link 125-b, a backhaul link 132-b, a midhaul link 162-b, fronthaul link 168-b).

The processor 830 may be a general-purpose processing component that supports various operations (such as applications) of the device 805. The memory 825 may be a general-purpose storage component that stores code executable by the processor 830. Such code may include instructions that, when executed by the processor 830, cause the device 805 to perform various functions (such as to support an application of the device 805).

For examples in which the device 805 is a network entity 105 in a disaggregated architecture, one or more components of the device 805 may be located at one or more of a CU 160-b, a DU 165-b, or an RU 170-b, one or more of which may include aspects of the processing system 820, the processor 830, the memory 825, or the transceiver 810. Functions of the device 805 may be performed at different components or an operation may be divided between different components (such as different functions being supported by aspects of the CU 160-b, the DU 165-b, or the RU 170-b, the transceiver 810, the processor 830, the memory 825, the processing system 820, or any combination thereof). For example, the processing system 820 may be a component of one or more of the CU 160-b, the DU 165-b, or the RU 170-b. In some examples, interfaces between components of device 805 (such as CU 160-b, DU 165-b, RU 170-b) may support communication at a protocol layer or between protocol layers of a protocol stack.

In some examples, the processing system 820 may manage aspects of communication with the core network 150-b (such as via a backhaul link 132). For example, the processing system 820 may manage the transfer of data communication for UEs 115 with a gateway of the core network 150-b. In some examples, the processing system 820 may manage communication with one or more other network entities 105 and may include a controller or scheduler for controlling communication with UEs 115 (such as in cooperation with the one or more other network entities 105). In some examples, the processing system 820 may support an interface (such as X2 interface, Xn interface) to provide communication between network entities 105.

The processing system 820 may be an example of a processing system 145 or a processing system 700. For example, the processing system 820 may include processor circuitry 835 and memory circuitry 840 that stores code, and the processing system 820 may be configured to cause the device 805 to perform operations that support network assistance and trigger based reporting for energy efficient quantization. Although the processing system 820 is illustrated as a separate component, which may involve a separate chip, chipset, or other module, in some implementations, one or more functions described with reference to the processing system 820 may be supported by or performed by a transceiver 810, antenna(s) 815, a processor 830, memory 825, or any combination thereof, such that a processing system 820 may include one or more of a transceiver 810, antenna(s) 815, a processor 830, memory 825, or any combination thereof. Further, processor circuitry 835 and memory circuitry 840 each may be implemented at the device 805 in accordance with an aggregated architecture, or the processor circuitry 835 and the memory circuitry 840 may be implemented at one or more of a CU 160-b, a DU 165-b, or an RU 170-b in accordance with a disaggregated architecture.

By including or configuring the processing system 820 for operation in the device 805 as described herein, may support techniques for improved decoding operations at a receiving device (e.g., a UE 115) by leveraging assistance information provided by the network relating to the wireless channel to more efficiently perform quantization of the input signal(s).

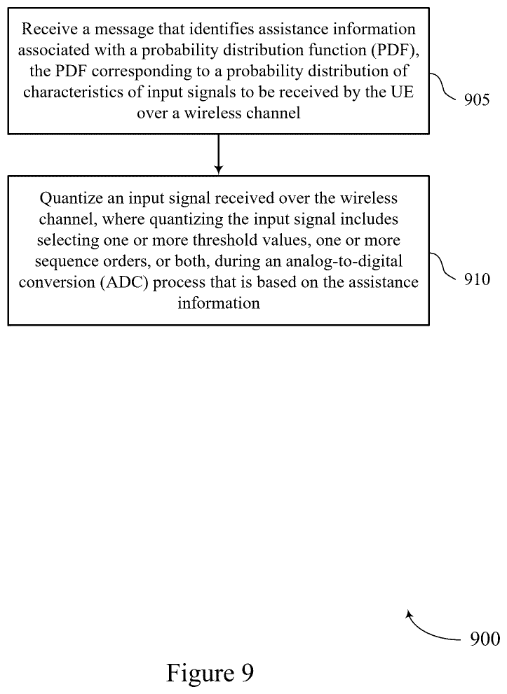

FIG. 9 shows an example of a method 900 that supports network assistance and trigger based reporting for energy efficient quantization. Operations of the method 900 may be performed by a UE or its components (such as using a processing system configured to cause the UE 115 to perform one or more of the operations) as described herein.

At 905, the method may include receiving a message that identifies assistance information associated with a PDF, the PDF corresponding to a probability distribution of characteristics of input signals to be received by the UE over a wireless channel. In some examples, aspects of the operations of 905 may be performed by an assistance information manager 525.

At 910, the method may include quantizing an input signal received over the wireless channel, where quantizing the input signal includes selecting one or more threshold values, one or more sequence orders, or both, during an ADC process that is based on the assistance information. In some examples, aspects of the operations of 910 may be performed by a quantization manager 530.

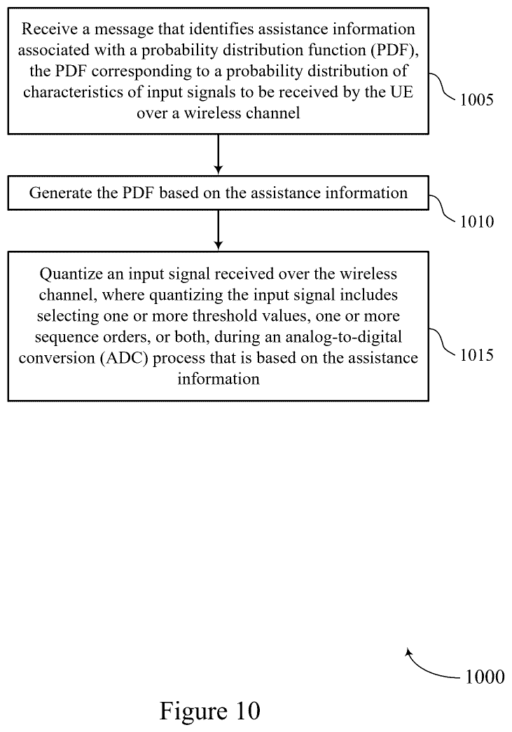

FIG. 10 shows an example of a method 1000 that supports network assistance and trigger based reporting for energy efficient quantization. Operations of the method 1000 may be performed by a UE or its components (such as using a processing system configured to cause the UE 115 to perform one or more of the operations) as described herein.

At 1005, the method may include receiving a message that identifies assistance information associated with a PDF, the PDF corresponding to a probability distribution of characteristics of input signals to be received by the UE over a wireless channel. In some examples, aspects of the operations of 1005 may be performed by an assistance information manager 525.

At 1010, the method may include generating the PDF based on the assistance information. In some examples, aspects of the operations of 1010 may be performed by a PDF manager 535.

At 1015, the method may include quantizing an input signal received over the wireless channel, where quantizing the input signal includes selecting one or more threshold values, one or more sequence orders, or both, during an ADC process that is based on the assistance information. In some examples, aspects of the operations of 1015 may be performed by a quantization manager 530.

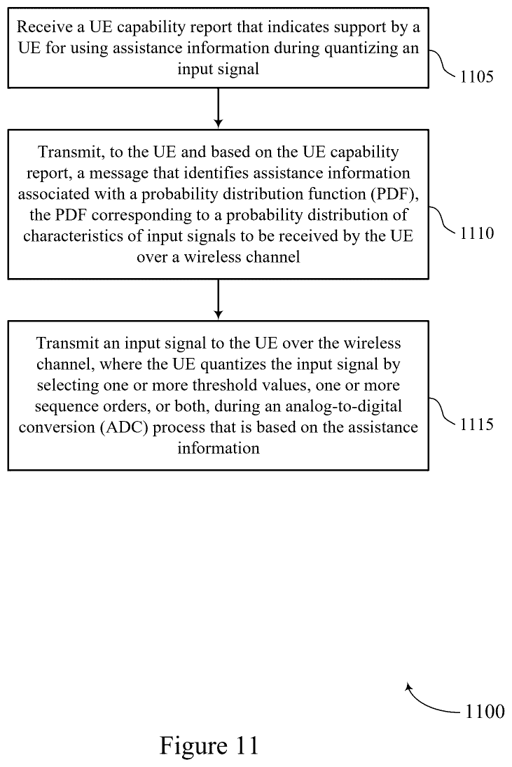

FIG. 11 shows an example of a method 1100 that supports network assistance and trigger based reporting for energy efficient quantization. Operations of the method 1100 may be performed by a network entity 105 or its components (such as using a processing system configured to cause the network entity to perform one or more operations) as described herein.

At 1105, the method may include receiving a UE capability report that indicates support by a UE for using assistance information during quantizing an input signal. In some examples, aspects of the operations of 1105 may be performed by a capability report manager 725.

At 1110, the method may include transmitting, to the UE and based on the UE capability report, a message that identifies assistance information associated with a PDF, the PDF corresponding to a probability distribution of characteristics of input signals to be received by the UE over a wireless channel. In some examples, aspects of the operations of 1110 may be performed by an assistance information manager 730.

At 1115, the method may include transmitting an input signal to the UE over the wireless channel, where the UE quantizes the input signal by selecting one or more threshold values, one or more sequence orders, or both, during an ADC process that is based on the assistance information. In some examples, aspects of the operations of 1115 may be performed by a signal manager 735.

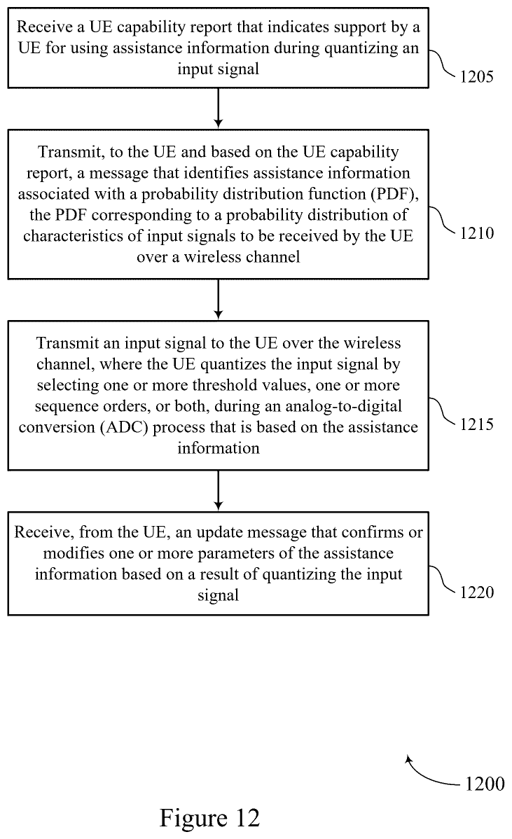

FIG. 12 shows an example of a method 1200 that supports network assistance and trigger based reporting for energy efficient quantization. Operations of the method 1200 may be performed by a network entity 105 or its components (such as using a processing system configured to cause the network entity to perform one or more operations) as described herein.

At 1205, the method may include receiving a UE capability report that indicates support by a UE for using assistance information during quantizing an input signal. In some examples, aspects of the operations of 1205 may be performed by a capability report manager 725.

At 1210, the method may include transmitting, to the UE and based on the UE capability report, a message that identifies assistance information associated with a PDF, the PDF corresponding to a probability distribution of characteristics of input signals to be received by the UE over a wireless channel. In some examples, aspects of the operations of 1210 may be performed by an assistance information manager 730.

At 1215, the method may include transmitting an input signal to the UE over the wireless channel, where the UE quantizes the input signal by selecting one or more threshold values, one or more sequence orders, or both, during an ADC process that is based on the assistance information. In some examples, aspects of the operations of 1215 may be performed by a signal manager 735.

At 1220, the method may include receiving, from the UE, an update message that confirms or modifies one or more parameters of the assistance information based on a result of quantizing the input signal. In some examples, aspects of the operations of 1220 may be performed by an update manager 745.

Implementation examples are described in the following numbered clauses:

Aspect 1: A method for wireless communications at a UE, comprising: receiving a message that identifies assistance information associated with a PDF, the PDF corresponding to a probability distribution of characteristics of input signals to be received by the UE over a wireless channel; and quantizing an input signal received over the wireless channel, wherein quantizing the input signal comprises selecting one or more threshold values, one or more sequence orders, or both, during an ADC process that is based at least in part on the assistance information.

Aspect 2: The method of aspect 1, wherein the assistance information comprises statistical information corresponding to the probability distribution across a spatial domain, across a time domain, or both.

Aspect 3: The method of any of aspects 1 through 2, further comprising: generating the PDF based at least in part on the assistance information.

Aspect 4: The method of any of aspects 1 through 3, wherein the assistance information is on a location basis, a frequency band basis, a time period basis, or any combination thereof.

Aspect 5: The method of any of aspects 1 through 4, wherein the assistance information comprises a time period during which the probability distribution is valid, a frequency span within which the probability distribution is valid, or both.

Aspect 6: The method of any of aspects 1 through 5, wherein the assistance information comprises a measurement request, further comprising: performing a channel measurement via a measurement resource identified in the assistance information, wherein quantizing the input signal is based at least in part on a result of the channel measurement.

Aspect 7: The method of any of aspects 1 through 6, further comprising: transmitting a UE capability report that indicates support for using the assistance information during quantizing the input signal, wherein the message is received based at least in part on the UE capability report.

Aspect 8: The method of any of aspects 1 through 7, further comprising: transmitting an update message that confirms or modifies one or more parameters of the assistance information based at least in part on a result of quantizing the input signal.

Aspect 9: The method of aspect 8, wherein the update message is transmitted based on an occurrence of a trigger condition associated with an accuracy level observed during quantizing the input signal that is based at least in part on the assistance information.

Aspect 10: A method for wireless communications at a network entity, comprising: receiving a UE capability report that indicates support by a UE for using assistance information during quantizing an input signal; transmitting, to the UE and based at least in part on the UE capability report, a message that identifies assistance information associated with a PDF, the PDF corresponding to a probability distribution of characteristics of input signals to be received by the UE over a wireless channel; and transmitting an input signal to the UE over the wireless channel, wherein the UE quantizes the input signal by selecting one or more threshold values, one or more sequence orders, or both, during an ADC process that is based at least in part on the assistance information.

Aspect 11: The method of aspect 10, wherein the assistance information comprises statistical information corresponding to the probability distribution across a spatial domain, across a time domain, or both.

Aspect 12: The method of any of aspects 10 through 11, wherein the assistance information is on a location basis, a frequency band basis, a time period basis, or any combination thereof.

Aspect 13: The method of any of aspects 10 through 12, wherein the assistance information comprises a time period during which the probability distribution is valid, a frequency span within which the probability distribution is valid, or both.

Aspect 14: The method of any of aspects 10 through 13, wherein the assistance information comprises a measurement request, further comprising: transmitting, to the UE, a reference signal for a channel measurement via a measurement resource identified in the assistance information.

Aspect 15: The method of any of aspects 10 through 14, further comprising: receiving, from the UE, an update message that confirms or modifies one or more parameters of the assistance information based at least in part on a result of quantizing the input signal.

Aspect 16: The method of aspect 15, wherein the update message is transmitted based on an occurrence of a trigger condition associated with an accuracy level observed during quantizing the input signal that is based at least in part on the assistance information.

Aspect 17: A UE for wireless communications, comprising a processing system that includes processor circuitry and memory circuitry that stores code, the processing system configured to cause the UE to perform a method of any of aspects 1 through 9.

Aspect 18: A UE for wireless communications, comprising at least one means for performing a method of any of aspects 1 through 9.

Aspect 19: A non-transitory computer-readable medium storing code for wireless communications, the code comprising instructions executable by one or more processors to perform a method of any of aspects 1 through 9.

Aspect 20: A network entity for wireless communications, comprising a processing system that includes processor circuitry and memory circuitry that stores code, the processing system configured to cause the network entity to perform a method of any of aspects 10 through 16.

Aspect 21: A network entity for wireless communications, comprising at least one means for performing a method of any of aspects 10 through 16.

Aspect 22: A non-transitory computer-readable medium storing code for wireless communications, the code comprising instructions executable by one or more processors to perform a method of any of aspects 10 through 16.

It should be noted that methods described herein describe possible implementations. Other implementations in accordance with the described techniques are possible, including implementations in which operations are rearranged or otherwise modified relative to the described methods. Further, aspects from two or more of the described methods may be combined.

Although aspects of 5G or 6G systems may be described for purposes of example and corresponding terminology may be used in the description, the techniques described herein are applicable beyond 5G, or 6G networks. For example, the described techniques may be applicable to other communication systems such as Institute of Electrical and Electronics Engineers (IEEE) 802.11 (Wi-Fi), IEEE 802.20, Flash-OFDM, or other systems and radio technologies not explicitly mentioned herein.

As used herein, a processing system (such as a processing system 140, a processing system 145) includes processor (or “processing”) circuitry in the form of one or multiple processors, microprocessors, processing units (such as central processing units (CPUs), graphics processing units (GPUs), neural processing units (NPUs) (also referred to as neural network processors or deep learning processors (DLPs)), or digital signal processors (DSPs)), processing blocks, application-specific integrated circuits (ASICs), programmable logic devices (PLDs), or other discrete gate or transistor logic or circuitry (any one or more of which may be generally referred to herein individually as a “processor” or collectively as “the processor” or “the processor circuitry”). Such processors may be individually or collectively configurable or configured to perform functions or operations described herein. A group of processors collectively configurable or configured to cause a device to perform a set of functions may include a first processor configured to cause the device to perform a first function of the set and a second processor configured to cause the device to perform a second function of the set. In some other examples, each of a group of processors may be configured to cause a device to perform a same set of functions.

As used herein, a processing system (such as a processing system 140, a processing system 145) also includes memory circuitry in the form of one or multiple memory devices, memory blocks, memory elements, or other discrete gate or transistor logic or circuitry, each of which may include or implement tangible storage media such as random-access memory (RAM) or read-only memory (ROM), or combinations thereof (any one or more of which may be generally referred to herein individually as a “memory” or collectively as “the memory” or “the memory circuitry”). One or more of the memories may be coupled (such as operatively, communicatively, electronically, electrically) with one or more processors of the processor circuitry and may individually or collectively store processor-executable code or instructions (such as software) that, when executed by one or more of the processors, may cause a device (such as configure the device, using one or more of the processors) to perform functions or operations described herein. Additionally, or alternatively, in some examples, one or more of the processors may be configured to cause a device to perform functions or operations described herein without requiring configuration by software. As used herein, “software” shall be construed to mean instructions, instruction sets, code, code segments, program code, programs, subprograms, software modules, applications, software applications, software packages, routines, subroutines, objects, executables, threads of execution, procedures, or functions, among other examples, whether referred to as software, firmware, middleware, microcode, hardware description language, or otherwise.

As used herein, a processing system (such as a processing system 140, a processing system 145) may include or be coupled with one or more modems (such as a cellular modem, a 5G-compliant modem, a 6G-compliant modem). In some examples, one or more processors of a processing system may include or implement one or more of the modems. A processing system also may include or be coupled with multiple radios (collectively “the radio”), multiple RF chains, or multiple transceivers, each of which may in turn be coupled with one or more of multiple antennas. In some examples, one or more processors of a processing system may include or implement one or more of the radios, RF chains, or transceivers. An RF chain may include one or more filters, mixers, oscillators, amplifiers, analog-to-digital converters (ADCs), or other devices that convert between an analog signal (such as for transmission or reception via an air interface) and a digital signal (such as for processing by processor circuitry).

As described herein, being “configured to,” being “configurable to,” and being “operable to” may be used interchangeably and may be associated with a capability, when executing code (such as processor-executable code, instructions) stored in memory circuitry (such as a non-transitory computer-readable medium, of the memory circuitry, storing code for wireless communication that is executable by a processing system) or otherwise, to perform one or more of the functions described herein.

As used herein, the term “determine” or “determining” can encompass one or more of a variety of actions. For example, “determining” can include one or more of calculating, computing, processing, deriving, detecting, estimating, looking up, inferring, ascertaining, measuring, resolving, selecting, obtaining, identifying, interpreting, demodulating, decoding, reading, establishing, forming, or generating, among other examples. In some such examples, determining can involve a processing system performing some type of calculating, computing, deriving, estimating, inferring, ascertaining, resolving, predicting, or other processing to obtain one or more numerical values, sets, elements, or other information or results. In some such examples, determining can involve a processing system identifying, looking up, investigating or otherwise obtaining some type of value, set, element, or other information or result from a table, data structure, database, or an implementation of memory, such as from a larger set of values, sets, or elements or other information or results. In some such examples, determining can involve a processing system identifying, interpreting, demodulating, decoding, detecting, reading, or otherwise obtaining some type of value, set, element, or other information or result signaled in, for example, a received wireless signal. In some such examples, determining can involve a processing system performing a measurement, such as on a received signal.

As used herein, a phrase referring to “at least one of” or “one or more of” a list of items refers to any combination of those items, including single members. For example, “at least one of: a, b, or c” is intended to cover: a, b, c, a-b, a-c, b-c, and a-b-c. Additionally, as used herein, a phrase referring to “a” or “an” element refers to one or more of such elements acting individually or collectively to perform the recited function(s). Thus, the terms “a,” “at least one,” “one or more,” and “at least one of one or more” may be interchangeable. For instance, for a claim that refers to “a” component performing one or more functions, each of the individual functions may be performed by a single component or by any combination of multiple components, and subsequent reference to a component introduced with the article “a” using the term “the” may refer to any or all of the single or multiple components. Thus, a component introduced with the article “a” may be understood to mean “one or more” components, and referring to “the” component subsequently in the claims may be understood to be equivalent to referring to “at least one of the one or more” components. Additionally, as used herein, a “set” can refer to one or more items, and a “subset” can refer to a whole set or less than the whole set, but not an empty set. Additionally, as used herein, the term “or” is intended to be interpreted in the inclusive sense, such as when referring to a series, and may be used interchangeably with the term “and/or,” unless otherwise explicitly indicated (for example, if used in conjunction with “either” or “only one of”). For example, “a or b” may include a only, b only, or a combination of a and b.

The disclosure is provided to enable a person having ordinary skill in the art to implement the described techniques. Modifications to the disclosure will be apparent to a person having ordinary skill in the art, and the techniques disclosed herein may be applied with other variations without departing from the scope of the disclosure. Thus, the disclosure is not limited to the examples and designs described herein but is to be accorded the broadest scope consistent with the principles and novel features disclosed herein.

What is claimed is:

1. A user equipment (UE), comprising:
a processing system that includes processor circuitry and memory circuitry that stores code, the processing system configured to cause the UE to:
receive a message that identifies assistance information associated with a probability distribution function (PDF), the PDF corresponding to a probability distribution of characteristics of input signals to be received by the UE over a wireless channel; and
quantize an input signal received over the wireless channel, wherein quantizing the input signal comprises selecting one or more threshold values, one or more sequence orders, or both, during an analog-to-digital conversion (ADC) process that is based at least in part on the assistance information.

2. The UE of claim 1, wherein the assistance information comprises statistical information corresponding to the probability distribution across a spatial domain, across a time domain, or both.

3. The UE of claim 1, wherein the processing system is further configured to cause the UE to:
generate the PDF based at least in part on the assistance information.

4. The UE of claim 1, wherein the assistance information is on a location basis, a frequency band basis, a time period basis, or any combination thereof.

5. The UE of claim 1, wherein the assistance information comprises a time period during which the probability distribution is valid, a frequency span within which the probability distribution is valid, or both.

6. The UE of claim 1, wherein the assistance information comprises a measurement request, the processing system is configured to cause the UE to:
perform a channel measurement via a measurement resource identified in the assistance information, wherein quantizing the input signal is based at least in part on a result of the channel measurement.

7. The UE of claim 1, wherein the processing system is further configured to cause the UE to:
transmit a UE capability report that indicates support for using the assistance information during quantizing the input signal, wherein the message is received based at least in part on the UE capability report.

8. The UE of claim 1, wherein the processing system is further configured to cause the UE to:
transmit an update message that confirms or modifies one or more parameters of the assistance information based at least in part on a result of quantizing the input signal.

9. The UE of claim 8, wherein the update message is transmitted based on an occurrence of a trigger condition associated with an accuracy level observed during quantizing the input signal that is based at least in part on the assistance information.

10. A network entity, comprising:
a processing system that includes processor circuitry and memory circuitry that stores code, the processing system configured to cause the network entity to:
receive a user equipment (UE) capability report that indicates support by a UE for using assistance information during quantizing an input signal;
transmit, to the UE and based at least in part on the UE capability report, a message that identifies assistance information associated with a probability distribution function (PDF), the PDF corresponding to a probability distribution of characteristics of input signals to be received by the UE over a wireless channel; and
transmit an input signal to the UE over the wireless channel, wherein the UE quantizes the input signal by selecting one or more threshold values, one or more sequence orders, or both, during an analog-to-digital conversion (ADC) process that is based at least in part on the assistance information.

11. The network entity of claim 10, wherein the assistance information comprises statistical information corresponding to the probability distribution across a spatial domain, across a time domain, or both.

12. The network entity of claim 10, wherein the assistance information is on a location basis, a frequency band basis, a time period basis, or any combination thereof.

13. The network entity of claim 10, wherein the assistance information comprises a time period during which the probability distribution is valid, a frequency span within which the probability distribution is valid, or both.

14. The network entity of claim 10, wherein the assistance information comprises a measurement request, the processing system is configured to cause the network entity to:
transmit, to the UE, a reference signal for a channel measurement via a measurement resource identified in the assistance information.

15. The network entity of claim 10, wherein the processing system is further configured to cause the network entity to:
receive, from the UE, an update message that confirms or modifies one or more parameters of the assistance information based at least in part on a result of quantizing the input signal.

16. The network entity of claim 15, wherein the update message is transmitted based on an occurrence of a trigger condition associated with an accuracy level observed during quantizing the input signal that is based at least in part on the assistance information.

17. A method for wireless communications at a user equipment (UE), comprising:
receiving a message that identifies assistance information associated with a probability distribution function (PDF), the PDF corresponding to a probability distribution of characteristics of input signals to be received by the UE over a wireless channel; and
quantizing an input signal received over the wireless channel, wherein quantizing the input signal comprises selecting one or more threshold values, one or more sequence orders, or both, during an analog-to-digital conversion (ADC) process that is based at least in part on the assistance information.

18. The method of claim 17, wherein the assistance information comprises statistical information corresponding to the probability distribution across a spatial domain, across a time domain, or both.

19. The method of claim 17, further comprising:
generating the PDF based at least in part on the assistance information.

20. The method of claim 17, wherein the assistance information is on a location basis, a frequency band basis, a time period basis, or any combination thereof.
